(19) United States
(12) Patent Application Publication
(10) Pub. No.: US 2026/0059728 A1
(43) Pub. Date: Feb. 26, 2026

(54) CHARGING DEVICE, HEAT DISSIPATION CONTROL METHOD, AND NON-TRANSITORY STORAGE MEDIUM EMPLOYING METHOD

(71) Applicant: HON HAI PRECISION INDUSTRY CO., LTD., New Taipei (TW)

(72) Inventor: Yi-Yi Liu, New Taipei (TW)

(21) Appl. No.: 18/938,469

(22) Filed: Nov. 6, 2024

(30) Foreign Application Priority Data
Aug. 20, 2024 (CN) 202411146366.X

(51) Int. Cl. H05K 7/20

(52) U.S. Cl. CPC H05K 7/20945; H05K 7/20909

(57) ABSTRACT

A charging device for charging a powered device during a preset working temperature range includes: a power output end configured to couple a powered device; a controller configured to communicate with the powered device and obtain charging state signals of the powered device; a power circuit coupled with the controller and the power output end, and configured to output a charging voltage to the power output end to charge the powered device; and a heat dissipation device coupled with the controller. The controller is further configured to control a working state of the power circuit and a working state of the heat dissipation device according to the charging state signals of the powered device. A heat dissipation control method and a non-transitory storage medium are also provided.

### TECHNICAL FIELD

The subject matter herein generally relates to charging technologies.

### BACKGROUND

Charging devices generate heat during charging processes. If a charging device has a poor heat dissipation, a charging efficiency of the charging device may be low and may cause an unstable charging, or even cause damage to electronic components of the charging device.

How to keep a working temperature of the charging device within an appropriate range is a problem to be solved.

### BRIEF DESCRIPTION OF THE DRAWINGS

Implementations of the present disclosure will now be described, by way of embodiments, with reference to the attached figures.

FIG. 1 is a block diagram illustrating a charging device according to an embodiment of the present disclosure.

FIG. 2 is a connection diagram illustrating a powered device and the charging device according to an embodiment of the present disclosure.

FIG. 3 is a flowchart illustrating a heat dissipation control method according to an embodiment of the present disclosure.

FIG. 4 is a block diagram illustrating a computer device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. It should be noted that references to “an” or “one” embodiment in this disclosure are not necessarily to the same embodiment, and such references mean “at least one”.

Several definitions that apply throughout this disclosure will now be presented.

The term “coupled” is defined as connected, whether directly or indirectly through intervening components, and is not necessarily limited to physical connections. The connection can be such that the objects are permanently connected or releasable connected. The term “comprising,” when utilized, means “including, but not necessarily limited to”; it specifically indicates open-ended inclusion or membership in the so-described combination, group, series, and the like.

FIG. 1 illustrates one exemplary embodiment of a charging device 100.

The charging device 100 may include a power output end 110, a controller 120, a power circuit 130, and a heat dissipation device 140. The power output end 110 is configured to couple a powered device 200. The controller 120 is configured to communicate with the powered device 200 and obtain charging state signals of the powered device 200. The power circuit 130 is coupled with the controller 120 and the power output end 110, the power circuit 130 is configured to output a charging voltage to the power output end 110 to charge the powered device 200. The heat dissipation device 140 is coupled with the controller 120. The controller 120 is further configured to control a working state of the power circuit 130 and a working state of the heat dissipation device 140 according to the charging state signals of the powered device 200.

In one embodiment, the power output end 110 can be physically connected to the powered device 200 (for example, connected to the powered device 200 based on cables) for communication and power transmission. The controller 120 can control the power circuit 130 to output a voltage to supply power to the powered device 200, or charge the powered device 200. The controller 120 can also control a working state of the heat dissipation device 140 based on the a working state of the charging device 100.

For example, an input terminal of the power circuit 130 can be coupled to a power grid, the power circuit 130 can convert a voltage of the power grid into an objective voltage to charge the powered device 200.

The heat dissipation device 140 can be arranged near heating elements (such as the controller 120, the power circuit 130, conversion circuits, etc.). The heat dissipation device 140 can be arranged inside or outside the charging device 100. For example, the charging device 100 includes a housing with a cavity, the controller 120 and the power circuit 130 are both arranged in the cavity.

For example, the heating elements are arranged inside the housing and located near one sidewall of the housing, the heat dissipation device 140 can be arranged outside the housing and located near the sidewall outside the housing to assist the heating elements dissipating heat and maintain a temperature inside the cavity within an appropriate temperature range.

In one embodiment, the charging device 100 can be a charging pile, an energy storage device, etc. The controller 120 can be a chip with control function, such as a microcontroller unit (MCU), or a field-programmable gate array (FPGA). The power circuit 130 may include metal oxide semiconductor (MOS) transistors, relays, buck circuits, etc. The heat dissipation device 140 can be fans, condensers, cooling fins, etc.

Taking the charging device 100 as a charging pile and the powered device 200 as an electric vehicle as an example, the power output end 110 may include one or more charging guns. When the power output end 110 is not physically connected to the electric vehicle, the charging pile is in an idle state. The controller 120 can obtain first charging state signals indicating that the charging pile is in the idle state, the controller 120 can control a main switch of the power circuit 130 to remain off-state, and control the heat dissipation device 140 to remain in a standby mode.

When the power output end 110 is coupled (for example, physically connected) to the electric vehicle and the charging pile does not start to charge the electric vehicle, the controller 120 can obtain second charging state signals representing indicating that the electric vehicle and the charging pile are connected and the charging pile is not yet started charging. The controller 120 can control the power circuit 130 to output a first voltage according to a charging request of the electric vehicle, and control the heat dissipation device 140 to operate at a first heat dissipation power.

When the power output end 110 is coupled to one electric vehicle and the charging pile charges the electric vehicle with a small charging power, the controller 120 can obtain third charging state signals indicating that the charging power is mall, the controller 120 can control the power circuit 130 to output a second voltage to charge the electric vehicle according to a charging requirement of the electric vehicle, and control the heat dissipation device 140 to operate at a first heat dissipation power.

When the power output end is coupled to multiple electric vehicles and the charging pile charges the multiple electric vehicles with a larger charging power, the controller 120 can obtain fourth charging state signals indicating that the charging power is larger, the controller 120 can control the power circuit 130 to output a third voltage to charge the multiple electric vehicles according to charging requirements of the multiple electric vehicles (the main switch of the power circuit 130 remains on-state), and control the heat dissipation device 140 to operate at a second heat dissipation power.

In one embodiment, the first heat dissipation power is less than the second heat dissipation power, the first voltage is lees than the second voltage, the second voltage is lees than or equal to the third voltage.

When a connection between the power output end 110 and the electric vehicle is abnormal (for example, the charging gun is not properly plugged in), vehicle charging is suspended. The controller 120 can obtain fifth charging state signals indicating that the connection between the power output end 110 and the electric vehicle is abnormal, and the main switch of the power circuit 130 remains off-state, the controller 120 controls the heat dissipation device 140 working at the first heat dissipation power.

When the charging pile is faulty, the controller 120 can obtain sixth charging state signals indicating that the charging pile is faulty, the controller 120 controls the main switch of the power circuit 130 to be off-state, and controls the heat dissipation device 140 working at the first heat dissipation power.

The embodiment can obtain the charging state signals through the controller 120 to determine the current charging state, and then control the power circuit 130 according to the current charging state. The controller 120 can control the heat dissipation device 140 according to the charging state signals. In this way, the heat dissipation device 140 can dissipate heat while the charging device 100 charges the powered device 200 according to the current charging state, and a heat dissipation effect of the charging device 100 is good. The heat dissipation device 140 can be turned on before an internal heating of the charging device 100 to keep the temperature within an appropriate temperature range, electronic components inside the charging device 100 can operate at the appropriate temperature range to improve a charging efficiency.

In one embodiment, the heat dissipation device 140 includes one or more fans. The controller 120 controlling the working state of the heat dissipation device 140 includes: opening the one or more fans, closing the one or more fans, and adjusting speeds of the one or more fans.

In one embodiment, the charging state signals of the powered device 200 include control pilot (CP) state signals defined in an IEC61851 standard. The CP state signals are used for communication between electric vehicles and charging piles. The CP state signals can indicate charging states and control information through different voltage levels and different connection states.

In one embodiment, the controller 120 is configured to decode and convert the CP state signals to obtain control signals, and the control signals can be configured to control working states of the fans. For example, when the controller 120 receives the CP state signals, the controller 120 can decode and convert the CP state signals, to output corresponding control signals. The corresponding control signals can be configured to open the one or more fans, close the one or more fans, or adjust speeds of the one or more fans. The CP state signals can be pulse width modulation (PWM) signals, and the control signal can also be PWM signals.

In one embodiment, the charging device 100 may further include a temperature detection device 150. The temperature detection device 150 can be arranged in the charging device 100. The temperature detection device 150 is configured to detect a temperature (for example, work temperature or temperature at any time) of the charging device 100. The controller 120 is configured to control the heat dissipation device 140 to work/be switched on when the working temperature is greater than a first preset temperature. The controller 120 can also control the heat dissipation device 140 to stop working/ be switched off when the working temperature is less than a second preset temperature.

In one embodiment, the second preset temperature is less than the first preset temperature. The temperature detection device 150 can include one or more temperature sensors to detect the temperature of the charging device 100.

In one embodiment, when a voltage of the CP state signals is within a first voltage range, the voltage of the CP state signals may be negatively proportional to the speeds of the one or more fans.

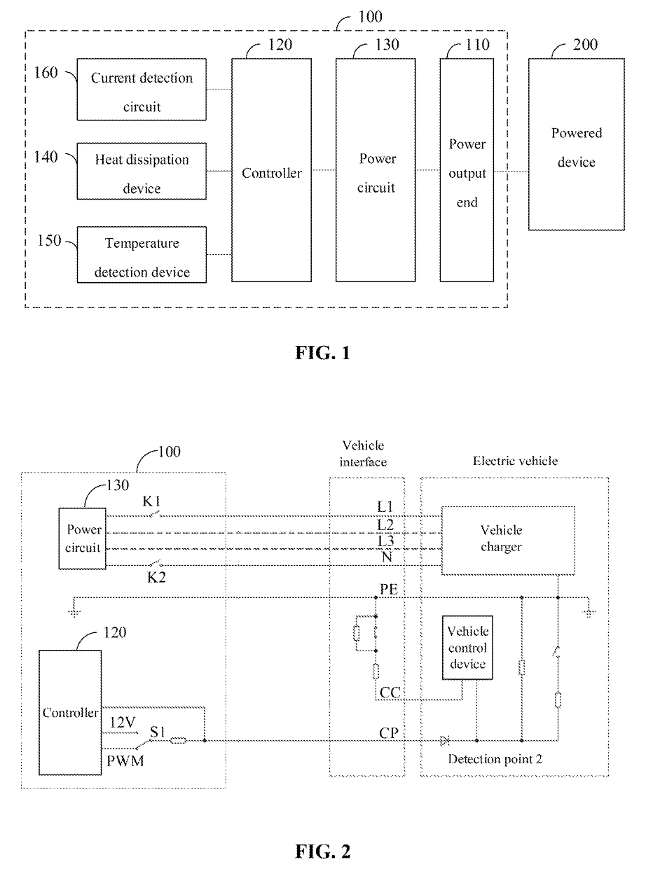

Referring to FIG. 2, the power output end 110 includes multiple power supply pins (L1, L2, L3, N) and a state detection pin (CP). The power supply pins are coupled to the power circuit 130 for outputting a supply voltage. The controller 120 can control power circuit 130 to output or stop outputting the supply voltage by controlling switches K1 and K2 being on-state or off-state, the controller 120 can further output PWM signals by the state detection pin to control a maximum charging current supported between the charging device 100 and the electric vehicle. The controller 120 can also obtain the charging state signals by detecting a voltage of the state detection pin. A switch S1 is arranged in the charging device 100 and is configured to confirm a connection state of the electric vehicle. A terminal of the switch S1 can be selected to connect a voltage pin of 12V or a PWM pin.

At an initial state, when the power output end 110 is not physically connected to the electric vehicle, the switch S1 is connected to the voltage pin of 12V. At this time, the controller 120 can detect that the voltage of the state detection pin is 11V~12V, which can determine that the electric vehicle is not connected and the heat dissipation device 140 does not need to dissipate heat, and the fans can remains in a standby state.

When the power output end 110 is physically connected to the electric vehicle, and the charging pile is not yet started charging, the controller 120 communicates with the electric vehicle to prepare for charging. A loop is formed between the charging device 100 and the electric vehicle through the power output end 110, and the electric vehicle may pull a voltage of a detection point 2 down to 9V through an internal circuit. The working power of the power circuit 130 is small and the heat generated by the power circuit 130 is less. The controller 120 can detect that the voltage of the state detection pin is 8V~10V, the controller 120 can determine that the electric vehicle is connected, and the fans can be controlled to be on-state, a speed of the fans can be low speed.

After a communication between the controller 120 and the electric vehicle is completed, the power circuit 130 can output the supply voltage to charge the electric vehicle according to a charging demand of the electric vehicle. If the number of connected electric vehicles is small, a supply voltage or a supply power of the charging pile may be small. The electric vehicle can adjust the voltage of the detection point 2 to 6V through the internal circuit. At this time, the working power of the power circuit 130 is relative small and the heat generated by the power circuit 130 is relative less. The controller 120 can detect that the voltage of the state detection pin is 5V~7V, the controller 120 can determine the charging power of the charging pile is relative small, and the controller 120 can further control the fans to increase dissipation power, so that the fans can rotates at a medium speed. If the number of connected electric vehicles is large, the supply voltage or the supply power of the charging pile may be large. The electric vehicle can adjust the voltage of the detection point 2 to 3V through the internal circuit. At this time, the working power of the power circuit 130 is large, and the heat generated by the power circuit 130 is large. The controller 120 can detects that the voltage of the state detection pin is 2V~4V, the controller 120 can determine the charging power of the charging pile is large, and the controller 120 can further control the fans to increase dissipation power, so that the fans can rotates at a high speed.

In one embodiment, the controller 120 can also synchronously monitor the temperature within the charging device 100 through the temperature detection device 150 and adjust the speeds of the fans according to the temperature within the charging device 100. If the temperature detection device 150 detects that the temperature within the charging device 100 is greater than the first preset temperature, the fans can be controlled to maintain high speed or continue to increase the speeds. If the temperature detection device 150 detects that the temperature within the charging device 100 is less than the second preset temperature, the fans can be controlled to stop rotating.

In one embodiment, the first preset temperature and the second preset temperature can be set according to a working temperature range of the charging device 100. The first voltage range can be set according to an actual application. For example, the voltage range can be set as a voltage range of the charging device 100 during normal charging. It can be understandable that when the charging demand for electric vehicles increases, the working power of the charging device 100 can be increased, and the heat generated by the charging device 100 can also be increased. In this embodiment, the controller 120 can reduce the voltage of the charging state signals to determine the current charging demand and increase the speeds of the fans at the same time. In this way, the controller 120 can determine the charging demand of the electric vehicles according to the charging state signals, and control the speeds of the fans to follow with the charging demand, and the fans can start to dissipate heat or increase the dissipation power before the temperature rises, so that the temperature inside the charging device 100 can be maintained in the appropriate temperature range, the charging efficiency can be improved, and a safety and a reliability of the charging device 100 can be ensured.

In one embodiment, the controller 120 can control the fans to operate at a first speed when the voltage of the CP state signals is within a second voltage range. The second voltage range can be smaller than the first voltage range. For example, a minimum voltage of the first voltage range is greater than a maximum voltage of the second voltage range.

In one embodiment, the second voltage range can be set according to the actual application. For example, the second voltage range can be set as a voltage range when the charging device 100 is abnormally connected to the electric vehicle. When the connection between the charging device 100 and the electric vehicle is abnormal, the internal circuit of the electric vehicle can adjust the voltage of the detection point 3 to 0V. When the controller 120 detects that the voltage of the state detection pin is 0V, the controller 120 can determine that the connection between the charging device 100 and the electric vehicle is abnormal, the controller 120 can control the power circuit 130 to stop working/be switched off, and the fans can be controlled to rotate at a low speed or the fans can be controlled according to the temperature inside the charging device 100. If the temperature inside the charging device 100 is higher than the first preset temperature, the fans can be controlled to rotate at a high speed. If the temperature inside the charging device 100 is less than the second preset temperature, the fans can be controlled to stop rotating. If the temperature inside the charging device 100 is between the first preset temperature and the second preset temperature, the fan can be controlled to rotate at a low speed or a medium speed.

In one embodiment, the controller 120 is further configured to control the fans to operate at a second speed when the voltage of the CP state signals is within a third voltage range. The second speed is greater than or equal to the first speed, and the third voltage range is smaller than the second voltage range.

In one embodiment, the third voltage range can be set according to the actual application. For example, the third voltage range can be set as a voltage range when the charging device 100 is failure. When the charging device 100 is failure (for example, a protection device of the charging device 100 is started), the voltage of the state detection pin is adjusted to -12V. When the controller 120 detects that the voltage of the state detection pin is -12V, the controller 120 can determine that the charging device 100 is failure. The controller 120 can control the power circuit 130 to stop working/ be switched off, and the fans can be controlled to rotate at a high speed or the fans can be controlled according to the temperature inside the charging device 100.

In one embodiment, if the temperature inside the charging device 100 is higher than the first preset temperature, the fans can be controlled to rotate at a high speed; if the temperature inside the charging device 100 is less than the second preset temperature, the fans can be controlled to stop rotating; if the temperature inside the charging device 100 is between the first preset temperature and the second preset temperature, the fans can be controlled to rotate at a low speed or a medium speed. The low speed, the medium speed and the high speed can be set according to actual needs. For example, if a maximum speed of the fan is 2000 revolutions per minute (RPM), a speed from 500 to 1000 RPM can be set as the low speed, a speed from 1000 to 1500 RPM can be set as the medium speed, and a speed from 1500 to 2000 RPM can be set as the high speed.

In one embodiment, referring to FIG. 1 again, the charging device 100 may further include a current detection circuit 160. The current detection circuit 160 is configured to detect a working current of the power circuit 130. The controller 120 is configured to control the power circuit 130 and the heat dissipation device 140 to stop working/ be switched off when the working current of the power circuit 130is greater than a preset current.

In one embodiment, the current detection circuit 160 can include a current detection resistor, the current detection resistor can be arranged at an output loop of the supply voltage. The preset current can be set according to a working current of the charging device 100. When the current detection circuit 160 detects that a current of the output loop is greater than the preset current, it indicates that a short circuit or an overcurrent exists in a circuit of the charging pile, and the controller 120 can control the power circuit 130 and the heat dissipation device 140 to stop working/ be switched off, to ensure a safe operation of the charging device 100.

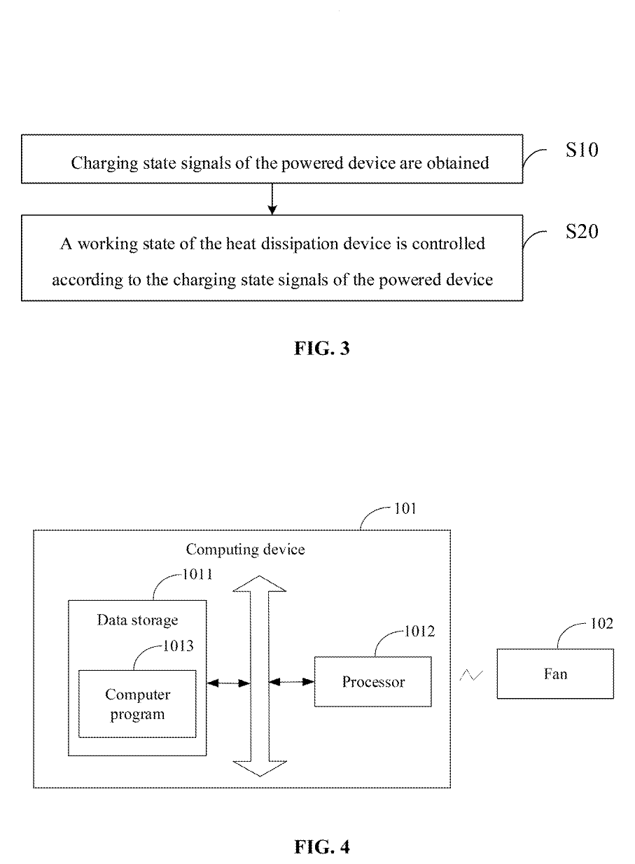

FIG. 3 illustrates one exemplary embodiment of a heat dissipation control method. The method can be applied to a charging device as shown in FIG. 1. The charging device can include a heat dissipation device, and the charging device is configured to couple with a powered device. The flowchart presents an exemplary embodiment of the method. The exemplary method is provided by way of example, as there are a variety of ways to carry out the method. Each block shown in FIG. 3 may represent one or more processes, methods, or subroutines, carried out in the example method. Furthermore, the illustrated order of blocks is illustrative only and the order of the blocks can change. Additional blocks can be added or fewer blocks may be utilized, without departing from this disclosure. The example method can be begin at block S10.

In block S10, charging state signals of the powered device are obtained.

In block S20, a working state of the heat dissipation device is controlled according to the charging state signals of the powered device.

In one embodiment, taking the charging device as a charging pile and the powered device as an electric vehicle as an example. When the charging pile is not physically connected to an electric vehicle, the charging pile is in an idle state. The charging pile can obtain first charging state signals indicating that a state of the charging pile is the idle state, and the heat dissipation device can be controlled to maintain a standby state.

When the charging pile is physically connected to an electric vehicle and the charging pile does not start to charge the electric vehicle. The charging pile can obtain second charging state signals representing indicating that the electric vehicle is connected to the charging pile and the charging pile is not yet started charging. The charging pile communicates with the electric vehicle to prepare for charging, and the heat dissipation device is controlled to operate at a first heat dissipation power.

When the charging pile is physically connected an electric vehicle and the charging pile charges the electric vehicle with a small charging power. The charging pile can obtain third charging state signals indicating that the charging power is mall. The charging pile can output a second voltage to charge the electric vehicle according to a charging requirement of the electric vehicle, and the heat dissipation device can be controlled to operate at a first heat dissipation power.

When the charging pile is coupled to multiple electric vehicles and the charging pile charges the multiple electric vehicles with a larger charging power. The charging pile can obtain fourth charging state signals indicating that the charging power is larger, the charging pile can output a third voltage to charge the multiple electric vehicles according to charging requirements of the multiple electric vehicles, and the heat dissipation device can be controlled to operate at a second heat dissipation power.

In one embodiment, the first heat dissipation power is less than the second heat dissipation power, the first voltage is lees than the second voltage, the second voltage is lees than or equal to the third voltage.

When a connection between the charging pile and the electric vehicle is abnormal, vehicle charging is suspended. The charging pile can obtain fifth charging state signals indicating that the connection between the charging pile and the electric vehicle is abnormal, and the charging pile stop to charge the electric vehicle, the heat dissipation device can be controlled to operate at the first heat dissipation power.

When the charging pile is faulty, the charging pile can obtain sixth charging state signals indicating that the charging pile is faulty, the charging pile stop to charge the electric vehicle, and the heat dissipation device can be controlled to operate at the first heat dissipation power.

In one embodiment, the charging state signals of the powered device include control pilot (CP) state signals defined in an IEC61851 standard.

The embodiment can obtain the charging state signals of the powered device to determine the current charging state, and then control output voltage of the charging device according to the current charging state. The charging device can further control the working state of the heat dissipation device according to the charging state signals. In this way, the charging device can dissipate heat while charging the powered device according to the current charging state, and a heat dissipation effect of the charging device is good. The heat dissipation device can be turned on before an internal heating of the charging device to keep the temperature within an appropriate temperature range, electronic components inside the charging device can operate at the appropriate temperature range to improve a charging efficiency.

Referring to FIG. 4, a computing device 101 may include at least one data storage 1011, at least one processor 1012, and a computer program 1013 that is stored in the data storage 1011 and can be run on the processor 1012. When the processor 1012 executes the computer program 1013, the heat dissipation control method can be realized in a charging device, such as block S10 to block S20 shown in FIG. 3 can be executed.

In one embodiment, the computing device 101 can be integrated in the charging device, that is, the computing device 101 can be a hardware module with data processing function in the charging device. For example, the processor 1012 can be a controller 20 as shown in FIG. 1.

The charging device further include a heat dissipation device. As shown in FIG. 4, the heat dissipation device includes a fan 102. When the processor 1012 executes the computer program 1013, a working state of the fan 102 can be controlled by the processor 1012.

In one embodiment, the computer program 1013 be divided into one or more modules/units, and the one or more modules/units are stored in the data storage 1011 and executed by processor 1012. The module or units may be a series of computer instruction segments capable for completing a specific function, and the instruction segments are used for describing a execution process of the computer program 1013 in the computing device 101.

In one embodiments, comparing with FIG. 4, the computing device 101 can include more or less elements, for example, the computing device 101 can further include communication devices, buses elements, etc.

In one embodiment, the processor 1012 can be a central processing unit (CPU), a microprocessor, a digital signal processors (DSP), an application specific integrated circuit (ASIC), a field-programmable gate array (FPGA), or other data processor chip that achieves the required functions.

The data storage 1011 can be used to store computer programs 40 and/or modules/units, and the processor 1012 can realize various functions of the computing device 101 by running or executing computer programs and/or modules/units stored in the data storage 1011 and calling up data stored in the data storage 1011. The data storage 1011 can be set in the computing device 101, or can be a separate external memory card, such as an SM card (Smart Media Card), an SD card (Secure Digital Card), or the like. The data storage 1011 can include various types of non-transitory computer-readable storage mediums. For example, the data storage 1011 can be an internal storage system, such as a flash memory, a random access memory (RAM) for the temporary storage of information, and/or a read-only memory (ROM) for permanent storage of information. The data storage 1011 can also be an external storage system, such as a hard disk, a storage card, or a data storage medium.

The embodiment also provides a non-transitory storage medium, the non-transitory storage medium is configured to store computer instructions, and when the computer instructions are run on the computing device 101, causes the computing device 101 to perform the above-mentioned heat dissipation control method.

The embodiment also provides a computer program product, and when the computer program product is running on a computer device, the computer device is caused to perform the above-mentioned heat dissipation control method.

The embodiments shown and described above are only examples. Many details known in the field are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A charging device comprising:
a power output end configured to couple a powered device;
a controller configured to communicate with the powered device and obtain charging state signals of the powered device;
a power circuit coupled with the controller and the power output end, and configured to output a charging voltage to the power output end to charge the powered device; and
a heat dissipation device coupled with the controller,
wherein the controller is further configured to control a working state of the power circuit and a working state of the heat dissipation device according to the charging state signals of the powered device.

2. The charging device of claim 1, wherein the heat dissipation device comprises a fan, the controller controlling the working state of the heat dissipation device comprises: opening the fan, closing the fan, and adjusting a speed of the fan.

3. The charging device of claim 2, wherein the charging state signals of the powered device comprise control pilot (CP) state signals defined in an IEC61851 standard.

4. The charging device of claim 3, wherein the controller is further configured to decode and convert the CP state signals to obtain control signals, and the control signals are configured to control a working state of the fan.

5. The charging device of claim 3, wherein when a voltage of the CP state signals is within a first voltage range, the voltage of the CP state signals is negatively proportional to the speed of the fan.

6. The charging device of claim 5, wherein the controller is further configured to control the fan to operate at a first speed when the voltage of the CP state signals is within a second voltage range, and the second voltage range is smaller than the first voltage range.

7. The charging device of claim 6, wherein the controller is further configured to control the fan to operate at a second speed when the voltage of the CP state signals is within a third voltage range, the second speed is greater than or equal to the first speed, and the third voltage range is smaller than the second voltage range.

8. The charging device of claim 1, further comprising a temperature detection device arranged in the charging device, and the temperature detection device is configured to detect a work temperature of the charging device; the controller is further configured to control the heat dissipation device to be switched on when the working temperature is greater than a first preset temperature, and control the heat dissipation device to be switched off when the working temperature is less than a second preset temperature; and the second preset temperature is less than the first preset temperature.

9. A heat dissipation control method applied in a charging device, the charging device comprising a heat dissipation device, and coupled with a powered device, the heat dissipation control method comprising:
obtaining charging state signals of the powered device; and controlling a working state of the heat dissipation device according to the charging state signals of the powered device.

10. The heat dissipation control method of claim 9, wherein the charging state signals of the powered device comprise control pilot (CP) state signals defined in an IEC61851 standard.

11. The heat dissipation control method of claim 10, wherein the heat dissipation device further comprises a fan, controlling the working state of the heat dissipation device according to the charging state signals of the powered device comprises:
opening the fan, closing the fan, or adjusting a speed of the fan according to the CP state signals.

12. The heat dissipation control method of claim 11, further comprising:
decoding and converting the CP state signals to obtain control signals; controlling a working state of the fan according to the control signals.

13. The heat dissipation control method of claim 9, further comprising:
detecting a work temperature of the charging device;
controlling the heat dissipation device to be switched on when the working temperature is greater than a first preset temperature; and
controlling the heat dissipation device to be switched off when the working temperature is less than a second preset temperature, wherein the second preset temperature is less than the first preset temperature.

14. A non-transitory storage medium having stored thereon instructions that, when executed by a processor of a charging device, causes the charging device to perform a heat dissipation control method, the heat dissipation control method comprising:
obtaining charging state signals of a powered device, wherein the charging device is coupled with the powered device, and the charging device comprises a heat dissipation device; and
controlling a working state of the heat dissipation device according to the charging state signals of the powered device.
